(19) United States
(12) Patent Application Publication
(10) Pub. No.: US 2023/0230923 A1
(43) Pub. Date: Jul. 20, 2023

(54) MICROELECTRONIC DIE INCLUDING SWAPPABLE PHY CIRCUITRY AND SEMICONDUCTOR PACKAGE INCLUDING SAME

(71) Applicant: Intel Corporation, Santa Clara, CA (US)

(72) Inventors: Gerald Pasdast, San Jose, CA (US); Zhiguo Qian, Chandler, AZ (US); Sathya Narasimman Tiagaraj, San Jose, CA (US); Lakshmipriya Seshan, Sunnyvale, CA (US); Peipei Wang, San Jose, CA (US); Debendra Das Sharma, Saratoga, CA (US); Srikanth Nimmagadda, Bangalore (IN); Zuoguo Wu, San Jose, CA (US); Swadesh Choudhary, Mountain View, CA (US); Narasimha Lanka, Dublin, CA (US)

(73) Assignee: Intel Corporation, Santa Clara, CA (US)

(21) Appl. No.: 17/824,974

(22) Filed: May 26, 2022

(30) Foreign Application Priority Data
Dec. 30, 2021 (IN) 202141061702

(51) Int. Cl. H01L 23/538; H01L 25/16; H01L 23/00

(52) U.S. Cl. CPC H01L 23/5382; H01L 23/5386; H01L 24/16; H01L 25/16; H01L 2224/16225

(57) ABSTRACT

A microelectronic device, a semiconductor package including the device, an IC device assembly including the package, and a method of making the device. The device includes a substrate; physical layer (PHY) circuitry on the substrate including a plurality of receive (RX) circuits and a plurality of transmit (TX) circuits; electrical contact structures at a bottom surface of the device; signal routing paths extending between the electrical contact structures on one hand, and, on another hand, at least some of the RX circuits or at least some of the TX circuits; and electrical pathways leading to the PHY circuitry and configured such that at least one of: an enable signal input to the device is to travel through at least some of the electrical pathways to enable a portion of the PHY circuitry; or a disable signal input to the device is to travel through at least some of the electrical pathways to disable a corresponding portion of the PHY circuitry.

### CROSS-REFERENCE TO RELATED APPLICATION

This application claims the benefit of and priority from Indian Patent Application No. 202141061702 filed Dec. 30, 2021, the entire disclosure of which is incorporated herein by reference.

### TECHNICAL FIELD

This disclosure relates generally to die-to-die (D2D) in-package interconnect technology, for example to express interconnect (CXi) interconnects.

### BACKGROUND

In-package die-to-die (D2D) interconnect technologies include, at a high level, standard interconnect regimes and advanced interconnect regimes to provide signal connection between two dies provided on a top surface of the package substrate. A standard interconnect regime involves the provision of signal routing traces typically within organic build-up layers of the package substrate to couple the two dies to one another. An advanced interconnect regime provides a silicon bridge structure embedded within a package substrate, where the silicon bridge structure includes signal routing traces therein to couple the two dies to one another. An example of a silicon bridge structure for an advanced package interconnect regime includes, for example, and embedded multi-die interconnect bridge (EMIB), or a chip-on-wafer-on-substrate (CoWoS). A given D2D interconnect technology or regime may be selected based on a number of factors, such as, for example, bandwidth density requirements (e.g. bandwidth per millimeter (BW/mm) and/or BW/mm^2), a die/package desired floorplan, and available form factors.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 is a cross sectional view of a microelectronic assembly including an example of a standard interconnect regime.

FIG. 2 is a cross sectional view of a microelectronic assembly including an example of an advanced interconnect regime.

FIG. 3 is a cross-sectional view of a microelectronic assembly according to an embodiment.

FIG. 4A is a bottom plan view of a first die including C4 bumps based on an advanced interconnect regime according to an embodiment.

FIG. 4B is a bottom plan view of a first die including C4 bumps based on an advanced interconnect regime according to an embodiment.

FIG. 5 illustrates an example layout 500 for bumpouts for a data rate of 16 gigatransfers per second (GT/s) on standard package traces (e.g., on a package with an approximately 110 micron pitch), in accordance with various embodiments.

FIG. 6 illustrates an example layout 600 for bumpouts for a data rate of 32 GT/S on standard package traces (e.g., on a package with an approximately 110 micron pitch), in accordance with various embodiments.

FIG. 7 illustrates an example layout 700 for bumpouts for a data rate of 16 GT/s on standard package traces (e.g., on a package with an approximately 110 micron pitch), in accordance with various embodiments.

FIG. 8 illustrates an example layout 800 for bumpouts for a data rate of 32 GT/s on standard package traces (e.g., on a package with an approximately 110 micron pitch), in accordance with various embodiments.

FIG. 9 illustrates an example bumpout for an advanced package (e.g., EMIB or some other similar package with an approximately 45 micron pitch), in accordance with various embodiments.

FIG. 10 illustrates an example bumpout on advanced package traces (e.g., on a package with an approximately 45 micron pitch), in accordance with various embodiments.

FIG. 11 is a flow chart of a process according to some embodiments.

FIG. 12 is a cross-sectional side view of an integrated circuit device assembly that may include a microelectronic structure in accordance with any of the embodiments disclosed herein.

FIG. 13 is a block diagram of an example electrical device that may include a microelectronic structure, in accordance with any of the embodiments disclosed herein.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims. In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

The technologies described herein may be implemented in one or more electronic devices. Non-limiting examples of electronic devices that may utilize the technologies described herein include any kind of mobile device and/or stationary device, such as microelectromechanical systems (MEMS) based electrical systems, gyroscopes, advanced driving assistance systems (ADAS), 5G communication systems, cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments, the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of electronic devices, including semiconductor packages with passive heat spreaders, interface layers, TIMs, top dies, side dies, substrates, and package substrates.

As used herein the terms “top,” “bottom,” “upper,” “lower,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

Microelectronic assemblies including standard interconnect technologies tend to suffer from lower interconnect wire densities when compared to advanced package interconnect technologies. Using a silicon bridge under the advanced interconnect regime allows the provision of tighter pitched interconnects that allows larger signal bandwidth made possible by a higher density of tighter pitched electrically conductive structures (e.g. C4 bumps, smaller solder bumps or Cu-Cu connections) provided under each die.

The state of the art contemplates D2D physical layer configurations (PHYs) that are tailored to the in-package interconnect regime used for standard and advanced package substrates due to multiple factors including bump pitch differences and thus connections for a given PHY area.

As used herein, the term “PHY” may refer to a physical layer architecture within a die, including the circuitry therein, such as receive (RX) and transmit (TX) circuitry. That is, “PHY” may refer to logical and circuit architecture within a given die.

As used herein, reference to a “die” is meant to broadly refer to a die, a chiplet, or any other integrated circuit structure including circuitry therein and supported on a substrate.

The PHY within a given die according to the state of the art is configured differently based on whether the die is to be coupled to another die on a package using a standard interconnect regime or an advanced interconnect regime. According to the state of the art, the PHY in a die to be used with a standard interconnect regime is different in from the PHY to be used with an advanced interconnect regime. Thus, according to the state of the art, a die to be coupled to another die by way of in-package interconnects has a PHY configuration such that every distinct PHY circuit (e.g. every RX circuit or a TX circuit of the die) is connected to one or more electrical contact structures at a bottom region of the die (to face the package).

Some embodiments herein advantageously provide a plurality of dies (including chiplets) with identical PHY circuit design as between one another, wherein one die of the plurality of dies may have electrical contact structures thereon (e.g. controlled collapse for chip connection (C4) bumps) corresponding to a standard package interconnects on the receiving package, while another die of the plurality of dies may have electrical contact structures thereon corresponding to advanced package interconnects on the receiving package. Embodiments advantageously make it possible to provide identical dies for D2D signal interconnection through a package where any given die can be fitted with electrically conductive structures that correspond to standard package interconnects or to electrically conductive structures that correspond to advanced package interconnects. According to some embodiments, a die according to embodiments is configured to allow a mapping of signal paths (i.e. traces and vias) therein to fit either a standard or an advanced bump configuration, including bump pitch.

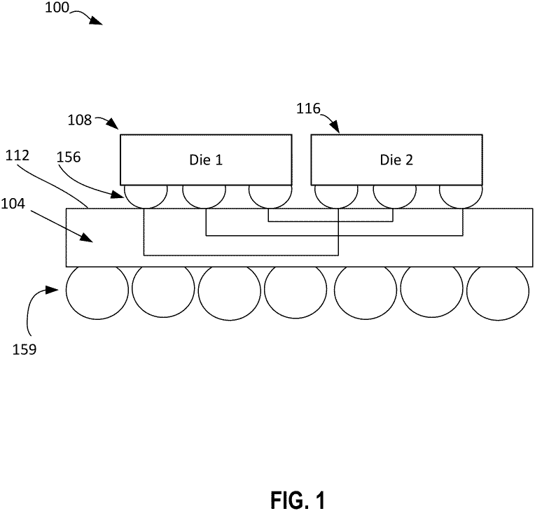

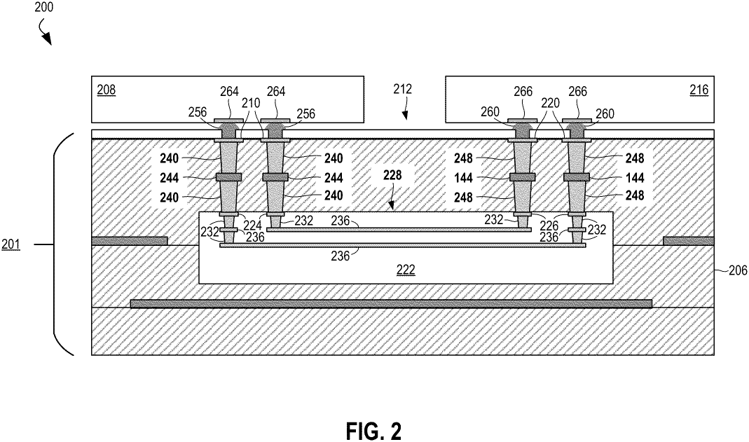

An explanation will now follow below regarding the state-of-the-art in the context of FIGS. 1 and 2.

FIG. 1 is a cross-sectional view of an example microelectronic assembly or semiconductor package 100 including a package substrate 104, and two dies 108 and 116 supported on a top surface 112 of the package substrate 104. In FIG. 1, the package substrate 104 is shown as including signal routing traces 136 therein coupling die 108 to die 116. Substrate 104 may include a core layer including sublayers of a non-conductive material, such as glass, silicon or an organic material, and the traces 136 extending through the sublayers to conduct electrical signals therethrough. Dies 108 and 116 are each electrically coupled to a top surface 112 of the package substrate 104 via electrical contact structures or joints 156, such as C4 bumps, connecting to die conductive contacts on the respective dies and substrate conductive contacts (not shown). The C4 bumps couple the dies 108 and 116 together by way of traces 136 extending through the package substrate 104 and providing conductive pathways between the dies 108 and 116. Additional electrically conductive structures 159 are provided at a bottom surface of the package substrate.

FIG. 2 is a cross-sectional view of an example microelectronic assembly or semiconductor package 200 including an interconnect bridge 222 embedded within a package substrate 204, and two dies 208 and 216 supported on a top surface 212 of the package substrate 204. In FIG. 2, the combination of the package substrate 204 and interconnect bridge 222 will together be referred to as a microelectronic structure 201. Substrate 204 may include a core layer including sublayers of a non-conductive material, such as glass, silicon or an organic material, and conductive traces 244 extending through the sublayers to conduct electrical signals therethrough. A first integrated circuit die 208 is attached to a top surface 212 of the package substrate 204 via electrical contact structures or joints 256 connecting to die conductive contacts 264 and substrate conductive contacts 210. A second integrated circuit die 216 is attached to the face 212 via coupling components 260 connecting to die conductive contacts 266 and substrate conductive contacts 220.

Bridge conductive contacts 224 and 226 are located on a face 228 of the bridge 200. Bridge vias 232 and bridge conductive traces 236 provide conductive pathways between the conductive contacts 224 and 226. Substrate vias 240 and substrate conductive traces 244 provide conductive pathways from the substrate conductive contacts 210 to the bridge conductive contacts 224 and substrate vias 248 and substrate conductive traces 244 provide conductive pathways from the substrate conductive contacts 220 to the bridge conductive contacts 226. Together, conductive contacts 210, 220, 224, 226, vias 232, 240, 248, and conductive traces, 236, 244 provide conductive pathways between integrated circuit dies 208 and 216 and thus allow them to be communicatively coupled.

Although the embedded interconnect bridge 222 is shown as being fully embedded within the substrate component 204, in some embodiments, it can be partially embedded, with the bridge face 228 being part of the face 212 of the first substrate component 204. In such embodiments, the bridge conductive contacts 224 and 226 can be located at the face 212 of the substrate component 204 and the integrated circuit dies 208 and 216 can connect to the bridge conductive contacts 224 and 226 via coupling components 256 and 260, respectively.

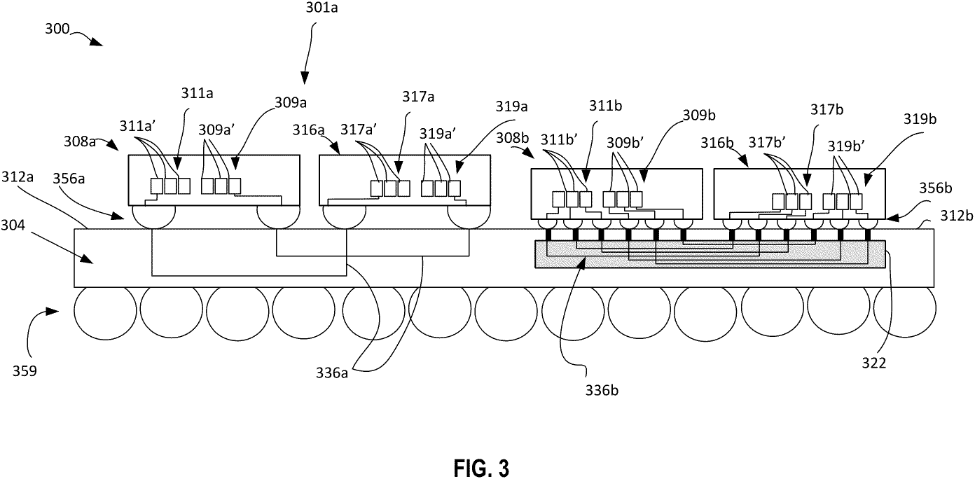

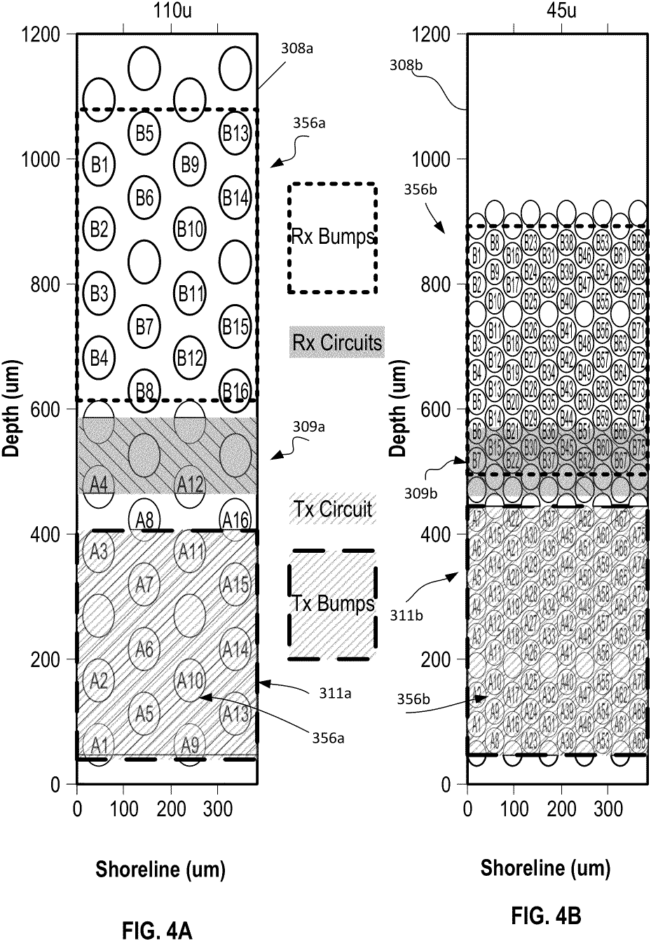

Many of the elements of the semiconductor package 100 of FIG. 1 or 200 of FIG. 2 are included in other ones of the accompanying drawings relating to some embodiments, for example FIGS. 3, 4A and 4B. A description of some elements may therefore not be repeated when discussing the drawings to be described below, and any of these elements may take any of the forms disclosed herein.

In addition, in the below descriptions of FIGS. 3, 4a and 4b, although reference is made to C4 bumps to refer to the electrical contact structures coupling dies to a package substrate, embodiments are not so limited, and include within their scope the provision of electrical contact structures not including C4 bumps, or bumps, such as electrical contact structures in the form of contact pads, pins or wire bonds based on application needs.

FIG. 3 is a cross-sectional view of an example microelectronic assembly or semiconductor package 300 according to some embodiments. In the embodiment of FIG. 3, the on-package dies all include a set of identical PHY circuitries therein, but yet allow a mapping of signal paths (i.e. traces and vias) therein to fit electrical contact structures corresponding to a standard or an advanced electrical contact structure configuration.

In FIG. 3, the microelectronic assembly 300 includes a package substrate 304 including electrical contact structures 359 at a bottom surface thereof to allow connection to a motherboard or larger system (in the shown example, structures 359 being implemented as C4 bumps, although other examples are within the scope of embodiments), and four dies 308a, 316a, 308b, 316b supported on a top surface thereof, where pairs of the four dies are coupled to one another through an in-package D2D interconnect provided in package substrate 304 by way of respective bumpouts including C4 bumps 356a and 356b. Substrate 304 may include a core layer including sublayers of a non-conductive material, such as glass, silicon or an organic material. The four dies 308a, 316a, 308b and 316b are identical to one another in terms of a set of PHY circuitries therein, as they each contain identical sets of RX and TX circuitries, as will be explained further below. However, while dies 308a and 316a include electrical contact structures 356a (such as C4 bumps) at bottom surfaces thereof that are configured to be coupled to one another through signal routing paths including traces 336a extending through the material of the package substrate 304 (standard interconnect regime), dies 308b and 316b on the other hand are configured to be coupled to one another through signal routing paths including traces 336b that extend through a silicon bridge embedded within the package substrate 304 (advanced interconnect regime).

Thus, the microelectronic assembly 300 includes a standard interconnect portion 301a, and an advanced interconnect portion 301b. The standard interconnect portion 301a includes, in addition to the underlying corresponding portion of the package substrate 304, first die 308a and second die 316a, both supported on a top surface 312a of the package substrate 304. Dies 308a and 316a are coupled to one another in the same manner as the dies 108 and 116 of FIG. 1, that is, using a standard interconnect regime. The advanced interconnect portion 301b includes, in addition to the underlying corresponding portion of the package substrate 304, first die 308b and second die 316b, both supported on a top surface 312b of the package substrate 304. Dies 308b and 316b are coupled to one another in the same manner as the dies 208 and 216 of FIG. 2, that is, using an advanced interconnect regime.

For standard interconnect portion 301a, the package substrate 304 is shown as including signal routing paths including traces 336a therein coupling die 308a to die 316a and extending through the sublayers of the substrate to conduct electrical signals therethrough. Dies 308a and 316a are each electrically coupled to a top surface 312a of the package substrate 304 via electrical contact structures or joints 356a, such as C4 bumps, connecting to die conductive contacts on the respective dies and substrate conductive contacts (not shown). Each of dies 308a and 316a includes a set of PHY circuitry therein.

The first die of the standard interconnect portion, die 308a includes PHY circuitry including RX circuitry 309a and TX circuitry 311a. RX circuitry 309a includes individual RX circuits 309a′, and TX circuitry 311a includes individual TX circuits 311a′. The second die of the standard interconnect portion, die 316a, includes PHY circuitry including RX circuitry 317a and TX circuitry 319a. RX circuitry 317a includes individual RX circuits 317a′, and TX circuitry 319a includes individual TX circuits 319a′. The dies 308a and 316a are identical to one another in terms of their respective PHY circuitries (as suggested in FIG. 3), although the shown depiction shows die 308a having its TX circuitry oriented toward the left side of the figure, and die 316a having its TX circuitry turned and facing toward the right side of the figure.

In the standard interconnect portion 301a, each of dies 308a and 316a includes at least a PHY circuitry (a RX circuitry and/or a TX circuitry) that is not coupled to any C4 bump. Thus, each of dies 308a and 316a has at least one PHY circuitry from which there is no electrical coupling to a C4 bump. Thus, in the standard interconnect portion 301a, there are redundant or non-functional PHY circuitries.

For advanced interconnect portion 301b, the package substrate 304 is shown as including an interconnect bridge 322 including signal routing paths including traces 336b therein coupling die 308b to die 316b and extending through bridge to conduct electrical signals therethrough. Dies 308b and 316b are each electrically coupled to a top surface 312b of the package substrate 304 via electrical contact structures or joints 356b, such as C4 bumps, connecting to die conductive contacts on the respective dies and substrate conductive contacts (not shown). Each of dies 308b and 316b includes a set of PHY circuitries therein.

Although the embedded interconnect bridge 322 is shown as being fully embedded within the package substrate 304, in some embodiments, it can be partially embedded, with an upper surface of the bridge 322 being substantially coextensive with upper surface 312 of package substrate 304.

The first die of the advanced interconnect portion, die 308b includes PHY circuitry including RX circuitry 309b and TX circuitry 311b. RX circuitry 309b includes individual RX circuits 309b′, and TX circuitry 311b includes individual TX circuits 311b′. The second die of the advanced interconnect portion, die 316b, includes PHY circuitry including RX circuitry 317b and TX circuitry 319b. RX circuitry 317b includes individual RX circuits 317b′, and TX circuitry 319b includes individual TX circuits 319b′. The dies 308b and 316b are identical to one another in terms of their respective PHY circuitries (as suggested in FIG. 3), although the shown depiction shows die 308b having its TX circuitry oriented toward the left side of the figure, and die 316b having its TX circuitry turned and facing toward the right side of the figure.

In the advanced interconnect portion 301b, all PHY circuitries in each of dies 308b and 316b are connected to corresponding C4 bumps. Thus, each of dies 308b and 316b includes electrical couplings between all of its PHY circuitries and corresponding C4 bumps. Thus, in the advanced interconnect portion 301b, there are no redundant or non-functional PHY circuitries.

In the microelectronic assembly of FIG. 3, where a first die and a second die are coupled to one another through in-package interconnects, each active RX circuitry of the first die is coupled through the in-package D2D interconnects to a corresponding active TX circuitry of the second die, and each active TX circuitry of the first die is coupled through the in-package D2D interconnects to a corresponding active RX circuitry of the second die.

FIG. 4A is a bottom plan view of a die, including bumpouts, that is comparable to die 308a/316a (which will hereinafter be referred to as 308a as dies 308a and 316a are identical), while FIG. 4B is a bottom plan view of a die, including bumpouts, that is comparable to die 308b/316b (which will hereinafter be referred to as 308b as dies 308b and 316b are identical). Thus, FIG. 4A is a bottom plan view of a die 308a including C4 bumps at a bottom surface thereof where the C4 bumps correspond to a standard electrical contact structure configuration comparable to that shown for the standard interconnect portion 301a of FIG. 3, while FIG. 4B is a bottom plan view of a die 308b having a predetermined PHY circuitry, and including C4 bumps at a bottom surface thereof where the C4 bumps correspond to a standard or an advanced electrical contact structure configuration comparable to that shown for the standard interconnect portion 301a of FIG. 3.

In FIGS. 4A and 4B, the portions of the shown dies 308a and 308b that correspond to locations within the die for the RX circuits 309a/309b are shown by way of a solid shaded regions, while the portions of the shown dies 308a and 308b that correspond to the TX circuits 311a/311b are shown by way of a striped shaded region. Because the dies 308a and 308b are identical, they are, as noted previously, to include an identical architecture of RX circuits and TX circuits.

In FIGS. 4A and 4B, the bumpouts for C4 bumps at a bottom surface of die 308a and 308b as appropriate are depicted, for the shown embodiments, as round regions with some labeled and some unlabeled round regions, where the unlabeled round regions correspond to C4 bumps for VCC (power) or VSS (ground) signals for the die, and the labeled round regions correspond to C4 bumps that are to provide signal pathways to and from the PHY circuitries within the die. In the shown example, the TX circuits 311a/311b coincide (i.e. are physically superimposed) with their corresponding C4 bumps as shown by the complete overlap between the TX circuit region 311a/311b and the C4 bumps 356b, while the RX circuits 309a/309b are shown as partially overlapping with their corresponding C4 bumps. RX circuitries do not show a significant sensitivity to distance with respect to their C4 bumps, hence the possibility of a configuration such as the one shown in FIGS. 4A and 4B, although embodiments are not so limited, and include within their scope the positioning of RX or TX circuits with respect to their corresponding electrically conductive structures (e.g. C4 bumps) in any manner based on application needs. The shown dies may further include non-PHY circuitries, such as non-PHY logic circuitries, which may be positioned, in the shown examples of FIGS. 4A and 4B, in regions of the dies that are not shaded.

According to embodiments, a die includes enable/disable electrical pathways connected to the PHY circuitry such that an enable/disable signal input to the die is to cause the enable/disable electrical pathways to enable/disable less than all of at least one of the RX circuits or the TX circuits of the die (i.e. a portion (i.e. not all) of the RX circuits and/or a portion (i.e. not all) of the TX circuits). Thus, for die with a predetermined configuration of RX circuits and TX circuits according to embodiments, the electrical pathways are such that an enable signal input to the die can cause a portion of the RX circuits and/or of the TX circuits to be enabled. Similarly, for the same die, the electrical pathways are such that a disable signal input to the die can cause a portion and not all of the RX circuits and/or of the TX circuits to be disabled. For example, the electrical pathways may include electrical pathways extending to individual ones of the RX circuits and individual ones of the TX circuits. In such a case, an enable signal or a disable signal may be input into a portion of the electrical pathways to enable or disable the corresponding RX circuits or TX circuits. Alternatively, the electrical pathways may extend to distinct groups of the RX circuits and to distinct groups of the TX circuits, where each group may be enabled/disabled at the same time. In such a case, an enable signal or a disable signal may be input into electrical pathways corresponding to a group of RX circuits or TX circuits to enable or disable the corresponding RX circuits or TX circuits of the group. Regardless of the configuration of the enable/disable electrically conductive pathways, a die according to embodiments may further be configured such that an enable/disable signal input into the die is to enable/disable all of the PHY circuitries of the die. Enabling a portion of the PHY circuits and disabling another portion of the PHY circuits is consistent with a die that is to be bumped or bumped according to a standard interconnect regime, such as the one shown in standard interconnect portion 301a of FIG. 3. Enabling all of the PHY circuits is consistent with a die that is to be bumped or bumped according to an advanced interconnect regime, such as the one shown in advanced interconnect portion 301b of FIG. 3.

According to one embodiment, the enable/disable electrically conductive pathways of a die according to embodiments may include respective fuses or registers to be burned to disable or enable PHY circuits associated with a corresponding one of the electrically conductive pathways.

According to an embodiment, a boot logical configuration may determine how many PHY circuits to enable or disable.

Embodiments herein may implement a superset PHY circuitry design on a same die that contains all of the signaling and logic to support advanced package interconnects (for example: a PHY circuitry with 64 transmitters (TX) and 64 receivers (RX)) and use the same PHY circuitry design with some of the RX circuits and TX circuit disabled, and the die bumped out (e.g., with changes only to the upper metal and bump changes) to support a standard package interconnects (for example: a PHY with 16 TX + 16 RX) and thus disable the unused lanes.

In some embodiments, in addition for the existence in a die of enable/disable electrically conductive pathways that allow an enabling/disabling of only a portion of the PHY circuitry, if the bump layer and upper redistribution layer (RDL) layers of the die are stripped away, as already suggested above, it is be possible to observe the individual TX and RX PHY circuitries (one per bump). When assembled in an advanced package, a 1:1 connection may be observed between TX/RX circuits (or circuit blocks) with respect to signaling bumpout. When assembled in a standard package (e.g., in the x64 vs. x16 example described above) a 4:1 TX/RX circuit block ratio may be observed with respect to the signaling bumpout, meaning that one in every four PHY circuits on a die is connected to a bump.

Embodiments herein propose the provision of common PHY circuits in a die which may then be provided with electrical contact structures that are compatible with standard interconnect regimes through a package substrate, or electrical contact structures that are compatible with advanced interconnect regimes (e.g. EMIB, CoWoS, etc.) to provide D2D interconnects. The electrical contact structures may include bumps, such as C4 bumps, although other electrical contact structure configurations are within the scope of embodiments.

As an example, referring again to FIGS. 4A and 4B, standard package bumpouts for signaling may have pitches on the order of approximately 110 micrometers (µm, or “microns”), advanced packages bumpouts may have pitches on the order of approximately 45 microns to approximately 55 microns. With this example, advanced interconnect regime may have approximately 4 bumps in a same area as 1 bump for a standard interconnect regime.

It will be noted that both the values of the pitches for the standard and advanced packages, as well as the ratio between the two, may be different in different embodiments. For example the pitches may be higher or lower than described above. In one embodiment, pitches of standard packages may be between approximately 110 microns and approximately 130 microns, and the pitches of advanced packages may be between approximately 36 microns and 55 microns. This may make the ratio of the pitch of a standard package to the pitch of an advanced package as approximately 2:1, although in some real world embodiments it may be on the order of approximately 2.4:1. As noted, other embodiments may present higher or lower ratios as between pitches of advanced packages to those of standard packages.

Additionally, as bump pitches shrink (e.g., to be on the order of approximately 25 microns or 16 microns or less), the ratio of bumps of standard packages to bumps of advanced packages may change. For example, an advanced package may have 64 bumps in a given area, while a standard package may only have 4 bumps in that area. Alternatively, a standard package may have 16 bumps in a given area, while an advanced package may have 128 bumps in that area, 256 bumps in that area, etc. In other words, 16 standard bump to 64 advanced bump swappable ratio may be an applicable value for a range of bump pitches, and as the pitch ratio widens, the scalar ratio may similarly track that change.

Embodiments may provide a number of advantages. One such advantage is that embodiments allow for use of the same die or chiplet base (with only a need for re-taping out a new bump layer, bump via layer, and one or two metal layers below for connection, depending on the exact implementation) to be reused in both advanced and standard packages. Embodiments may also allow for a common logical interface and IO protocol to work in both advanced and standard packages. Embodiments increase the reusability and lifetime/longevity of a die by virtue of making the PHY circuitry design on the die such that the die is swappable between various in-package interconnect regimes., in this manner making a die according to embodiments more technically advantageous than dies of the prior art. This reusability may further save significant pre and post-silicon development cost, as well as allowing for faster time to market for different mix and match chiplet/system-on-chip (SOC) customizations for different market segments.

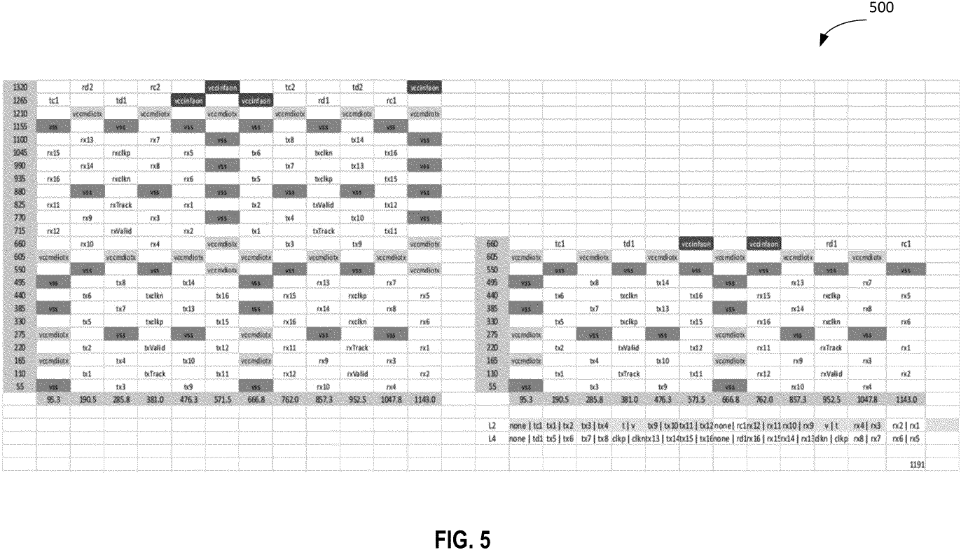

FIG. 5 illustrates an example layout 500 for bumpouts for a data rate of 16 gigatransfers per second (GT/s) on standard package traces (e.g., on a package with an approximately 110 micron pitch), in accordance with various embodiments. Specifically, FIG. 5 depicts two example bumpouts. The bumpout on the left (as oriented in FIG. 5) may be appropriate for use with 4 package routing layers, while the bumpout on the right (as oriented in FIG. 5) may be appropriate for use with 2 package routing layers (and thus having only half the signals as the bumpout on the left).

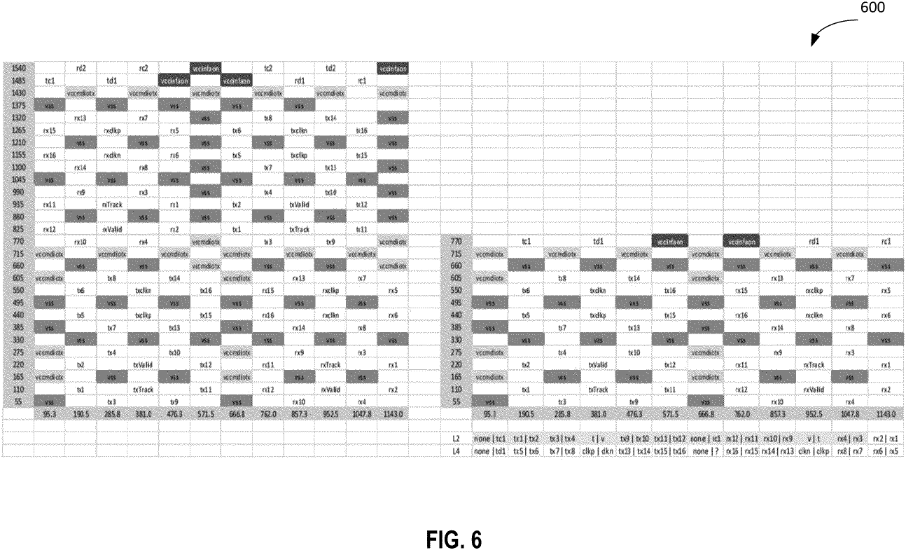

FIG. 6 illustrates an example layout 600 for bumpouts for a data rate of 32 GT/S on standard package traces (e.g., on a package with an approximately 110 micron pitch), in accordance with various embodiments. Specifically, FIG. 6 depicts two example bumpouts. The bumpout on the left (as oriented in FIG. 6) may be appropriate for use with 4 package routing layers, while the bumpout on the right (as oriented in FIG. 6) may be appropriate for use with 2 package routing layers (and thus having only half the signals as the bumpout on the left).

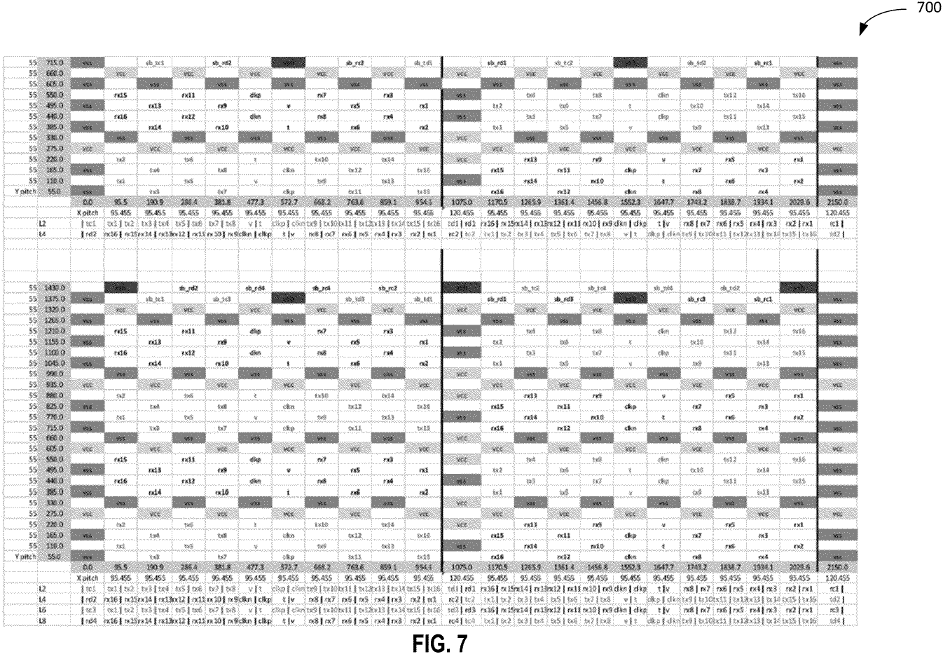

FIG. 7 illustrates an example layout 700 for bumpouts for a data rate of 16 GT/s on standard package traces (e.g., on a package with an approximately 110 micron pitch), in accordance with various embodiments. Specifically, FIG. 7 depicts two example bumpouts. The bumpout on the bottom (as oriented in FIG. 7) may be appropriate for use with 4 package routing layers, while the bumpout on the top (as oriented in FIG. 7) may be appropriate for use with 2 package routing layers (and thus having only half the signals as the bumpout on the bottom).

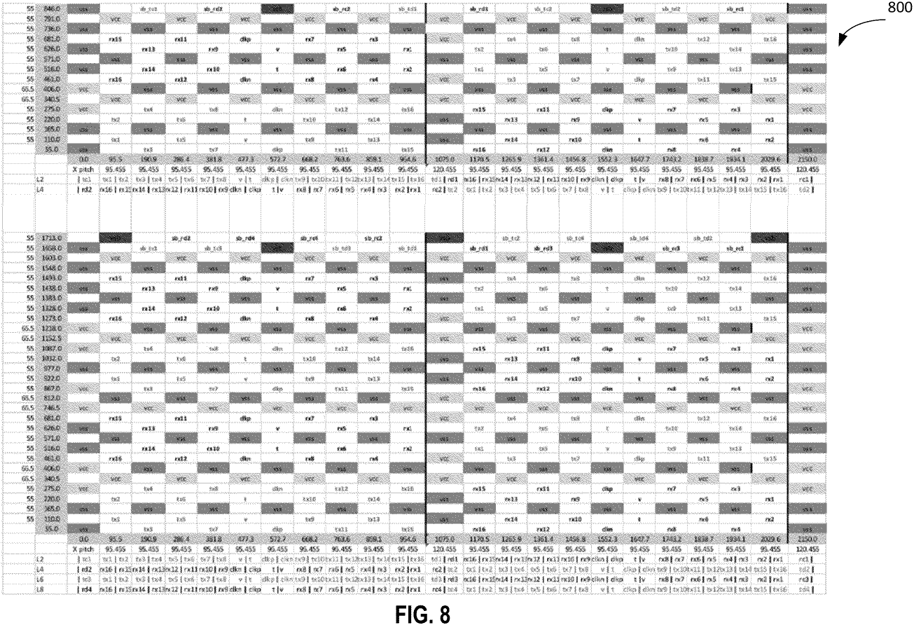

FIG. 8 illustrates an example layout 800 for bumpouts for a data rate of 32 GT/s on standard package traces (e.g., on a package with an approximately 110 micron pitch), in accordance with various embodiments. Specifically, FIG. 8 depicts two example bumpouts. The bumpout on the bottom (as oriented in FIG. 8) may be appropriate for use with 4 package routing layers, while the bumpout on the top (as oriented in FIG. 8 may be appropriate for use with 2 package routing layers (and thus having only half the signals as the bumpout on the bottom).

A difference between the embodiment shown in FIGS. 5 and 6 on the one hand, and 7 and 8 on the other, is that the pairs of figures show different ways of implementing the swappable PHY with different set of constraints on package routing. The pair in FIGS. 7 and 8 is better for lane-to-lane skew within the channel, due to better matching of lengths and all the signals of Tx and Rx to be on the same layer, while it is worse for on-die clock distribution and power delivery.

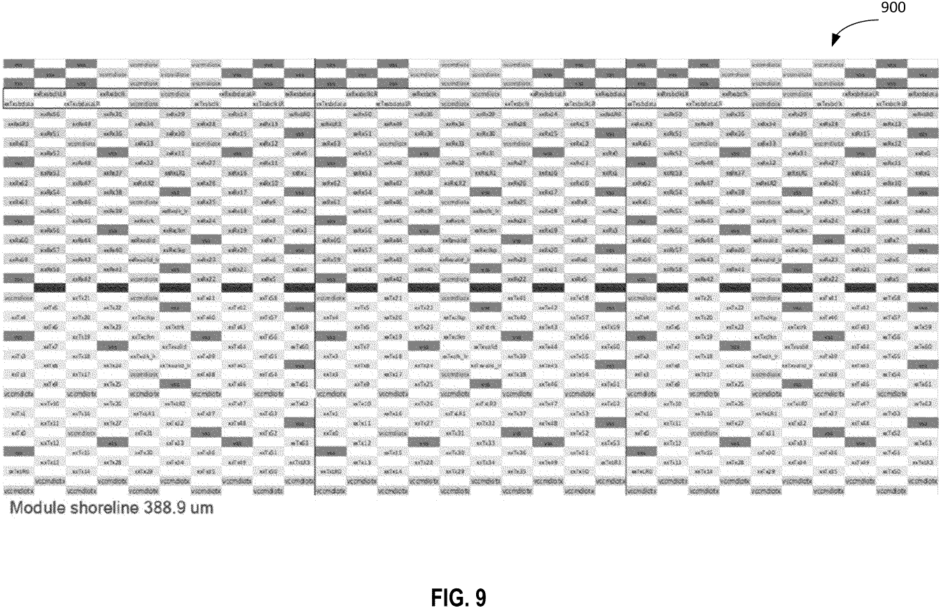

FIG. 9 illustrates an example layout 900 for bumpouts for an advanced package (e.g., EMIB or some other similar package with an approximately 45 micron pitch), in accordance with various embodiments. It will be noted that it may be possible to start with the bumpout of FIG. 9, and convert that bumpout to work on organic traces (e.g., a standard package bumpout) as described herein. Alternatively, it may be possible to start with the bumpout of any of FIGS. 5-8, and convert those bumpouts to work on advanced package bumpouts as described herein.

Generally, with respect to the bumpouts described for advanced packages, the lower left corner of the bump map may be considered the “origin” or start of a bump matrix. The following rules may be applied for an advanced package bump matrix:
The signals within a column may be preserved. For example, column 0 may contain the signals: txdataRD0, txdata0, txdata1, txdata2, txdata3, txdata4, txdata5, rxdata58, rxdata59, rxdata60, rxdata61, rxdata62, rxdata63, rxdataRD3 and txdatasb; and
The supply and VSS pattern shown in the bump matrices may be implemented. Enough VSS and supply bumps are to be provided to meet channel characteristics (FEXT and NEXT) and power delivery requirements.

Different bump matrices may be provided as described herein for one module or two module standard packages. The lower left corner of the bump maps may be considered the “origin” or start of a bump matrix. The signal exit order for x16 and x32 standard package bump matrices may be as shown herein.

The following rules may be implemented for a standard package bump matrix:
The signals within a column may be preserved. For example, for a x16 (one module standard package interface) shown in FIG. 70, Column 1 maycontain the signals: txdata0, txdata1, txdata9, txdata9 and txdatasb1.
The signals may exist the bump field. Layer 1 and Layer 2 are two different signal routing layers in a standard package.
One may follow the supply and VSS pattern shown in the bump matrices. It may be ensured that enough VSS and supply bumps are provided to meet channel characteristics (FEXT and NEXT) and power delivery requirements.

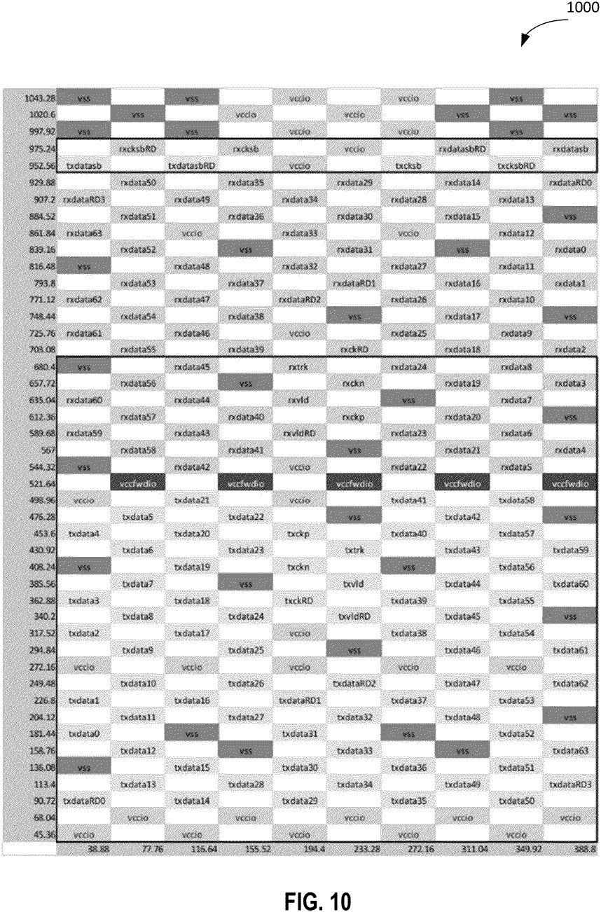

FIG. 10 illustrates an example layout 1000 for bumpouts on advanced package traces (e.g., on a package with an approximately 45 micron pitch), in accordance with various embodiments.

For packages with a standard pitch (e.g., the packages of FIGS. 7 or 8, or other packages such as those of FIGS. 5 or 6), it may be possible to create a unidirectional PHY by placing the TX on one side of the package, and RX on the other side. This embodiment may be possible if it is known that data is always going to flow through the package in one direction. As a result, for embodiments such as those described in FIGS. 7 or 8 (or other embodiments herein), such embodiments may run on a single layer package, thereby optimizing for bandwidth, area, and/or cost. The corresponding swappable advanced package may include only TX or RX, and hence unidirectional data flow at optimized cost, area, and/or bandwidth.

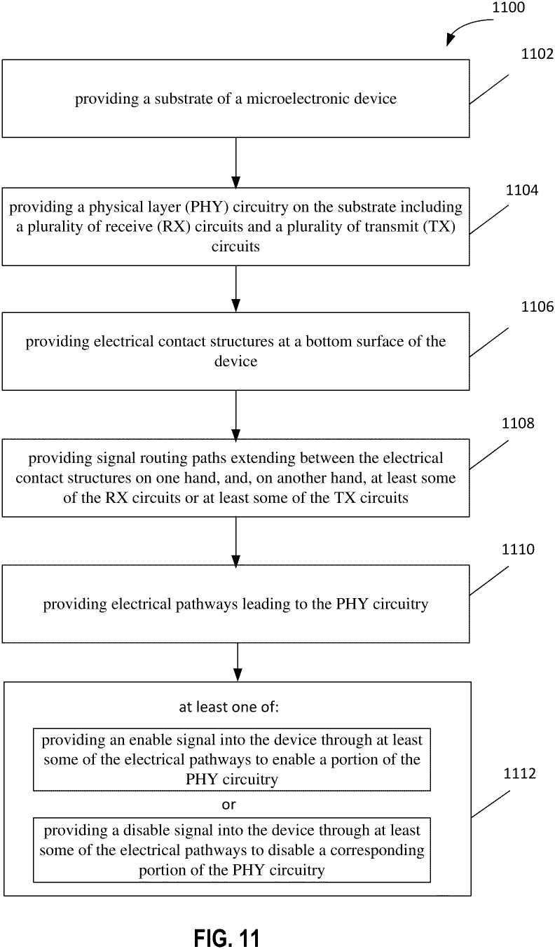

FIG. 11 shows a process 1to fabricate a microelectronic device, such as a die, according to some embodiments. At operation 1102, the process includes providing a substrate. At operation 1104, the process includes providing a physical layer (PHY) circuitry on the substrate including a plurality of receive (RX) circuits and a plurality of transmit (TX) circuits. At operation 1106, the process includes providing electrical contact structures at a bottom surface of the device. At operation 1108, the process incudes providing signal routing paths extending between the electrical contact structures on one hand, and, on another hand, at least some of the RX circuits or at least some of the TX circuits. At operation 1110, the process includes providing electrical pathways leading to the PHY circuitry. At operation 1112, the process includes at least one of: providing an enable signal into the device through at least some of the electrical pathways to enable a portion of the PHY circuitry; or providing a disable signal into the device through at least some of the electrical pathways to disable a corresponding portion of the PHY circuitry.

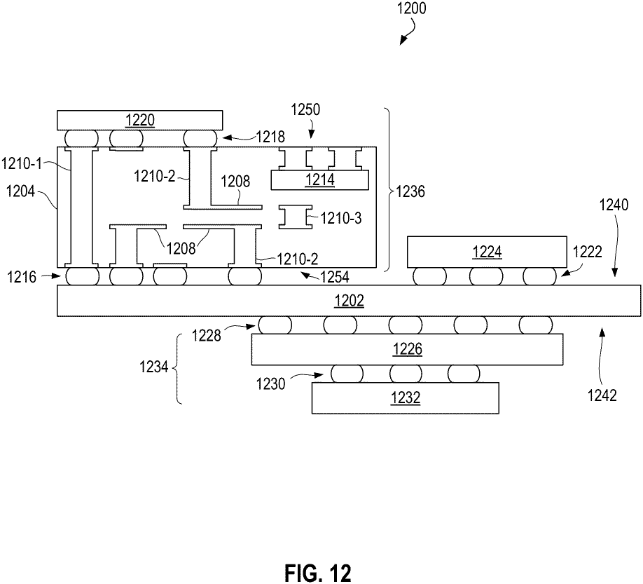

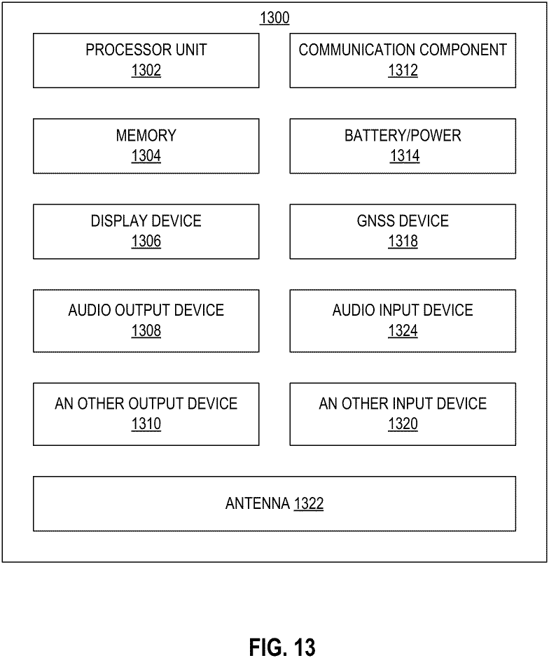

FIGS. 12 and 13 show some examples of an architecture that may include one or more microelectronic assemblies similar to the microelectronic assemblies described above in the context of embodiments as depicted by way of Example in FIGS. 3, 4a and 4b.

FIG. 12 is a cross-sectional side view of an integrated circuit device assembly 1200 that may include one or more integrated circuit structures each including any of the MCP packages of embodiments described herein. The integrated circuit device assembly 1200 includes a number of components disposed on a circuit board 1202 (which may be a motherboard, system board, mainboard, etc.). The integrated circuit device assembly 1200 includes components disposed on a first face 1240 of the circuit board 1202 and an opposing second face 1242 of the circuit board 1202; generally, components may be disposed on one or both faces 1240 and 1242. Any of the integrated circuit components discussed below with reference to the integrated circuit device assembly 1200 may include an integrated circuit structure including a cascaded a MCP as disclosed herein.

In some embodiments, the circuit board 1202 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1202. In other embodiments, the circuit board 1202 may be a non-PCB substrate. The integrated circuit device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1236 may include an integrated circuit component 1220 coupled to an interposer 1204 by coupling components 1218. The coupling components 1218 may take any suitable form for the application, such as the forms discussed above with reference to the coupling components 1216. Although a single integrated circuit component 1220 is shown in FIG. 12, multiple integrated circuit components may be coupled to the interposer 1204; indeed, additional interposers may be coupled to the interposer 1204. The interposer 1204 may provide an intervening substrate used to bridge the circuit board 1202 and the integrated circuit component 1220.

The integrated circuit component 1220 may be a packaged or unpackaged integrated circuit product that includes one or more integrated circuit dies. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1220, a single monolithic integrated circuit die comprises solder bumps attached to contacts on the die. The solder bumps allow the die to be directly attached to the interposer 1204. The integrated circuit component 1220 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1220 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1220 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1220 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1204 may spread connections to a wider pitch or reroute a connection to a different connection. For example, the interposer 1204 may couple the integrated circuit component 1220 to a set of ball grid array (BGA) conductive contacts of the coupling components 1216 for coupling to the circuit board 1202. In the embodiment illustrated in FIG. 12, the integrated circuit component 1220 and the circuit board 1202 are attached to opposing sides of the interposer 1204; in other embodiments, the integrated circuit component 1220 and the circuit board 1202 may be attached to a same side of the interposer 1204. In some embodiments, three or more components may be interconnected by way of the interposer 1204.

In some embodiments, the interposer 1204 may be formed as a PCB, including multiple metal layers separated from one another by layers of dielectric material and interconnected by electrically conductive vias. In some embodiments, the interposer 1204 may be formed of an epoxy resin, a fiberglass-reinforced epoxy resin, an epoxy resin with inorganic fillers, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through hole vias 1210-1 (that extend from a first face 1250 of the interposer 1204 to a second face 1254 of the interposer 1204), blind vias 1210-2 (that extend from the first or second faces 1250 or 1254 of the interposer 1204 to an internal metal layer), and buried vias 1210-3 (that connect internal metal layers).

In some embodiments, the interposer 1204 can comprise a silicon interposer. Through silicon vias (TSV) extending through the silicon interposer can connect connections on a first face of a silicon interposer to an opposing second face of the silicon interposer. In some embodiments, an interposer 1204 comprising a silicon interposer can further comprise one or more routing layers to route connections on a first face of the interposer 1204 to an opposing second face of the interposer 1204.

The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art. In embodiments where the interposer is a non-printed circuit board

The integrated circuit device assembly 1200 may include an integrated circuit component 1224 coupled to the first face 1240 of the circuit board 1202 by coupling components 1222. The coupling components 1222 may take the form of any of the embodiments discussed above with reference to the coupling components 1216, and the integrated circuit component 1224 may take the form of any of the embodiments discussed above with reference to the integrated circuit component 1220.

The integrated circuit device assembly 1200 illustrated in FIG. 12 includes a package-on-package structure 1234 coupled to the second face 1242 of the circuit board 1202 by coupling components 1228. The package-on-package structure 1234 may include an integrated circuit component 1226 and an integrated circuit component 1232 coupled together by coupling components 1230 such that the integrated circuit component 1226 is disposed between the circuit board 1202 and the integrated circuit component 1232. The coupling components 1228 and 1230 may take the form of any of the embodiments of the coupling components 1216 discussed above, and the integrated circuit components 1226 and 1232 may take the form of any of the embodiments of the integrated circuit component 1220 discussed above. The package-on-package structure 1234 may be configured in accordance with any of the package-on-package structures known in the art.

FIG. 13 is a block diagram of an example electrical device 1300 that may include one or more of the embodiment MCPs disclosed herein. For example, any suitable ones of the components of the electrical device 1300 may include one or more of the integrated circuit device assemblies 1200, integrated circuit components 1220, and/or embodiment MCPs disclosed herein. A number of components are illustrated in FIG. 13 as included in the electrical device 1300, but any one or more of these components may be omitted or duplicated, as suitable for the application. In some embodiments, some or all of the components included in the electrical device 1300 may be attached to one or more motherboards mainboards, or system boards. In some embodiments, one or more of these components are fabricated onto a single system-on-a-chip (SoC) die.

Additionally, in various embodiments, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1324 or an audio output device 1308, but may include audio input or output device interface circuitry (e.g., connectors and supporting circuitry) to which an audio input device 1324 or audio output device 1308 may be coupled.

The electrical device 1300 may include one or more processor units 1302 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1300 may include a memory 1304, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1304 may include memory that is located on the same integrated circuit die as the processor unit 1302. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1300 can comprise one or more processor units 1302 that are heterogeneous or asymmetric to another processor unit 1302 in the electrical device 1300. There can be a variety of differences between the processing units 1302 in a system in terms of a spectrum of metrics of merit including architectural, microarchitectural, thermal, power consumption characteristics, and the like. These differences can effectively manifest themselves as asymmetry and heterogeneity among the processor units 1302 in the electrical device 1300.

In some embodiments, the electrical device 1300 may include a communication component 1312 (e.g., one or more communication components). For example, the communication component 1312 can manage wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1312 may operate in accordance with other wireless protocols in other embodiments. The electrical device 1300 may include one or more antennas, such as antenna 1322 to facilitate wireless communications and/or to receive other wireless communications (such as AM or FM radio transmissions).

In some embodiments, the communication component 1312 may manage wired communications, such as electrical, optical, or any other suitable communication protocols (e.g., IEEE 802.3 Ethernet standards). As noted above, the communication component 1312 may include multiple communication components. For instance, a first communication component 1312 may be dedicated to shorter-range wireless communications such as Wi-Fi or Bluetooth, and a second communication component 1312 may be dedicated to longer-range wireless communications such as global positioning system (GPS), EDGE, GPRS, CDMA, WiMAX, LTE, EV-DO, or others. In some embodiments, a first communication component 1312 may be dedicated to wireless communications, and a second communication component 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any embedded or wired or wirelessly connected external device that generates an audible indicator, such speakers, headsets, or earbuds.

The electrical device 1300 may include an audio input device 1324 (or corresponding interface circuitry, as discussed above). The audio input device 1324 may include any embedded or wired or wirelessly connected device that generates a signal representative of a sound, such as microphones, microphone arrays, or digital instruments (e.g., instruments having a musical instrument digital interface (MIDI) output). The electrical device 1300 may include a Global Navigation Satellite System (GNSS) device 1318 (or corresponding interface circuitry, as discussed above), such as a Global Positioning System (GPS) device. The GNSS device 1318 may be in communication with a satellite-based system and may determine a geolocation of the electrical device 1300 based on information received from one or more GNSS satellites, as known in the art.

The electrical device 1300 may include another output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include another input device 1320 (or corresponding interface circuitry, as discussed above). Examples of the other input device 1320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1300 may be any other electronic device that processes data. In some embodiments, the electrical device 1300 may comprise multiple discrete physical components. Given the range of devices that the electrical device 1300 can be manifested as in various embodiments, in some embodiments, the electrical device 1300 can be referred to as a computing device or a computing system.

FIG. 10 is a flow chart of a process 1000 according to some embodiments. At operation 1002, the process includes providing a plurality of first dies. At operation 1004, the process includes providing an encapsulation layer on the first dies to form first layer of the semiconductor subassembly. At operation 1006, the process includes providing a first dielectric layer over the first layer to form a first layer and first dielectric layer subassembly. At operation 1008, the process includes providing a passive heat spreader interposer. At operation 1010, the process includes providing a second dielectric layer on the passive heat spreader interposer to form a passive heat spreader interposer and second dielectric layer subassembly. At operation 1012, the process includes forming an interface layer between and mechanically bonding the passive heat spreader interposer and the first layer, the interface layer providing a direct dielectric-to-dielectric bond including a first dielectric sublayer directly adjacent the first layer and formed from the first dielectric layer, and a second dielectric sublayer directly adjacent the first dielectric sublayer, formed from the second dielectric layer, and including an amorphous material. At operation 1014, the process includes providing a second layer including a substrate. At operation 1016, the process includes electrically coupling the substrate to the first dies.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of embodiments has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

In embodiments, the phrase “A is located on B” means that at least a part of A is in direct physical contact or indirect physical contact (having one or more other features between A and B) with at least a part of B.

In the instant description, “A is adjacent to B” means that at least part of A is in direct physical contact with at least a part of B.

In the instant description, “B is between A and C” means that at least part of B is in or along a space separating A and C and that the at least part of B is in direct or indirect physical contact with A and C.

In the instant description, “A is attached to B” means that at least part of A is mechanically attached to at least part of B, either directly or indirectly (having one or more other features between A and B).

The use of reference numerals separated by a “/”, such as “102/104” for example, is intended to refer to 102 or 104 as appropriate. Otherwise, the forward slash (“/”) as used herein means “and/or.”

The use of the techniques and structures provided herein can be detected using tools such as: electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, such tools can indicate an integrated circuit including at least one MCP including an interposer bonded to a MCP subassembly through direct dielectric-to-dielectric bonding as described herein.

In some embodiments, the techniques, processes and/or methods described herein can be detected based on the structures formed therefrom. In addition, in some embodiments, the techniques and structures described herein can be detected based on the benefits derived therefrom. Numerous configurations and variations will be apparent in light of this disclosure.

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” “according to some embodiments,” “in accordance with embodiments,” or “in embodiments,” which may each refer to one or more of the same or different embodiments. Furthermore, the terms “comprising,” “including,” “having,” and the like, as used with respect to embodiments of the present disclosure, are synonymous.

“Coupled” as used herein means that two or more elements are in direct physical contact, or that that two or more elements indirectly physically contact each other, but yet still cooperate or interact with each other (i.e. one or more other elements are coupled or connected between the elements that are said to be coupled with each other). The term “directly coupled” means that two or more elements are in direct contact.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 10⁷ Siemens per meter (S/m) at 20° C. Examples of such materials include Cu, Ag, Al, Au, W, Zn and Ni.

As used herein, an “integrated circuit structure” may include one or more microelectronic dies.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices. The term “signal” may refer to at least one current signal, voltage signal, magnetic signal, or data/clock signal. The meaning of “a,” “an,” and “the” include plural references. The meaning of “in” includes “in” and “on.”

The terms “substantially,” “close,” “approximately,” “near,” and “about,” generally refer to being within +/- 10% of a target value (unless specifically specified). Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors--BJT PNP/NPN, BiCMOS, CMOS, eFET, etc., may be used without departing from the scope of the disclosure. The term “MN” indicates an n-type transistor (e.g., nMOS, NPN BJT, etc.) and the term “MP” indicates a p-type transistor (e.g., pMOS, PNP BJT, etc.).

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

### EXAMPLES

Some non-limiting example embodiments are set forth below.

Example 1 includes a microelectronic device including: a substrate; physical layer (PHY) circuitry on the substrate including a plurality of receive (RX) circuits and a plurality of transmit (TX) circuits; electrical contact structures at a bottom surface of the device; signal routing paths extending between the electrical contact structures on one hand, and, on another hand, at least some of the RX circuits or at least some of the TX circuits; and electrical pathways leading to the PHY circuitry and configured such that at least one of: an enable signal input to the device is to travel through at least some of the electrical pathways to enable a portion of the PHY circuitry; and a disable signal input to the device is to travel through at least some of the electrical pathways to disable a corresponding portion of the PHY circuitry.

Example 2 includes the subject matter of Example 1, wherein the electrical pathways include at least one of a fuse or a register to at least one of enable or disable said corresponding portion of the PHY circuitry.

Example 3 includes the subject matter of Example 1, wherein the electrical pathways leading to the PHY circuitry are configured such that at least one of: an enable signal input to the device is to travel through at least some of the electrical pathways to enable ½ of the RX circuits and ½ of the TX circuit; and a disable signal input to the device is to travel through at least some of the electrical pathways to disable a remaining ½ of the RX circuits and ½ of the TX circuit.

Example 4 includes the subject matter of Example 1, wherein the electrical pathways leading to the PHY circuitry are configured such that at least one of: an enable signal input to the device is to travel through at least some of the electrical pathways to enable ¼ of the RX circuits and ¼ of the TX circuit; and a disable signal input to the device is to travel through at least some of the electrical pathways to disable a remaining ¾ of the RX circuits and ¾ of the TX circuit.

Example 5 includes the subject matter of Example 1, wherein some of the signal routing paths extend between corresponding ones of the electrical contact structures and all of the RX circuits, and some of the signal routing paths extend between corresponding ones of the electrical contact structures and all of the TX circuits.

Example 6 includes the subject matter of Example 1, wherein some of the signal routing paths extend between corresponding ones of the electrical contact structures and a portion of the RX circuits, and some of the signal routing paths extend between corresponding ones of the electrical contact structures and a portion of the TX circuits.

Example 7 includes the subject matter of Example 6, wherein: the portion of the RX circuits includes ½ of the RX circuits and the portion of the TX circuits includes ½ of the TX circuits; or the portion of the RX circuits includes ¼ of the RX circuits and the portion of the TX circuits includes or ¼ of the TX circuits.

Example 8 includes the subject matter of Example 1, wherein the RX circuits are at a first region of the device, and the TX circuits are at a second region of the device different from the first region.

Example 9 includes the subject matter of Example 1, wherein the signal routing paths include electrically conductive traces and vias of the device.

Example 10 includes the subject matter of Example 1, wherein the electrical contact structures include bumps.

Example 11 includes the subject matter of Example 10, wherein the bumps include C4 bumps.

Example 12 includes the subject matter of Example 1, wherein a pitch between the electrical contact structures is between about 110 microns and about 130 microns.

Example 13 includes the subject matter of Example 1, wherein a pitch between the electrical contact structures is between about 36 microns and about 55 microns.

Example 14, includes a semiconductor package, comprising: a package substrate; two pairs of dies on the package substrate including a first pair of dies including a first die and a second die, and a second pair of dies including a third die and a fourth die, wherein: individual ones of the dies include: a die substrate; physical layer (PHY) circuitry on the die substrate including a plurality of receive (RX) circuits and a plurality of transmit (TX) circuits; electrical contact structures at a bottom surface of the die; individual ones of the first die and the second die include signal routing paths extending between the electrical contact structures thereof on one hand, and, on another hand, all of the RX circuits and all the TX circuits thereof; individual ones of the third die and the fourth die include signal routing paths extending between the electrical contact structures thereof on one hand, and, on another hand, a portion of the RX circuits and a portion of the TX circuits thereof, wherein the package substrate includes first package signal routing paths extending between the first die and the second die to provide a device-to-device (D2D) signal interconnection therebetween, and second package signal routing paths extending between the first die and the second die to provide a device-to-device (D2D) signal interconnection therebetween.

Example 15 includes the subject matter of Example 14, wherein the portion of the RX circuits includes ½ of the RX circuits, and the portion of the TX circuits includes ½ of the TX circuits.

Example 16 includes the subject matter of Example 14, wherein the portion of the RX circuits includes ¼ of the RX circuits, and the portion of the TX circuits includes ¼ of the TX circuits.

Example 17 includes the subject matter of Example 14, wherein, for individual ones of the dies, the RX circuits are at a first region of the die, and the TX circuits are at a second region of the die different from the first region.

Example 18 includes the subject matter of Example 14, wherein, for individual ones of the dies, the signal routing paths include electrically conductive traces and vias of the die.

Example 19 includes the subject matter of Example 14, wherein, for individual ones of the dies, the electrical contact structures include bumps.

Example 20 includes the subject matter of Example 19, wherein, for individual ones of the dies, the electrical contact structures include controlled collapse chip collection bumps.

Example 21 includes the subject matter of Example 14, wherein, for the first die and the second die, a pitch between the electrical contact structures is between about 110 microns and about 130 microns, and for individual ones of the third die and the fourth die, a pitch between the electrical contact structures is between about 36 microns and about 55 microns.

Example 22 includes the subject matter of Example 14, wherein at least one of the first package signal routing paths and the second package signal routing paths extend through and are in contact with material layers of the package substrate.

Example 23 includes the subject matter of Example 22, wherein the material layers include an organic material.

Example 24 includes the subject matter of Example 14, wherein the package substrate defines a cavity therein, the package further including an interconnect bridge within the cavity, one of the at least one of the first package signal routing paths and the second package signal routing paths extending within the interconnect bridge.

Example 25 includes the subject matter of Example 14, wherein the first die, second die, third die and fourth die are identical to one another.

Example 26 includes the subject matter of Example 14, wherein individual ones of the dies include electrical pathways leading to the PHY circuitry and configured such that at least one of: an enable signal input to said individual ones of the dies is to travel through at least some of the electrical pathways to enable a portion of the PHY circuitry; or a disable signal input said individual ones of the dies is to travel through at least some of the electrical pathways to disable a corresponding portion of the PHY circuitry.

Example 27 includes the subject matter of Example 26, wherein, for individual ones of the dies, the electrical pathways include at least one of a fuse or a register to at least one of enable or disable said corresponding portion of the PHY circuitry.

Example 28 includes an integrated circuit (IC) device assembly including: a printed circuit board; and a plurality of integrated circuit components coupled to the printed circuit board, individual ones of the integrated circuit components including one or more semiconductor packages, individual ones of the semiconductor packages including: a package substrate; a plurality of dies on the package substrate, individual ones of the dies including: a die substrate; physical layer (PHY) circuitry on the die substrate including a plurality of receive (RX) circuits and a plurality of transmit (TX) circuits; electrical contact structures at a bottom surface of the die; signal routing paths extending between the electrical contact structures on one hand, and, on another hand, at least some of the RX circuits or at least some of the TX circuits; electrical pathways leading to the PHY circuitry and configured such that at least one of: an enable signal input to the die is to travel through at least some of the electrical pathways to enable a portion of the PHY circuitry; and a disable signal input to the die is to travel through at least some of the electrical pathways to disable a corresponding portion of the PHY circuitry; and wherein the package substrate includes package signal routing paths extending between a first die of the plurality of dies and a second die of the plurality of dies to provide a device-to-device (D2D) signal interconnection therebetween.

Example 29 includes the subject matter of Example 28, wherein, for individual ones of the dies, the electrical pathways include at least one of a fuse or a register to at least one of enable or disable said corresponding portion of the PHY circuitry.

Example 30 includes the subject matter of Example 28, wherein, for individual ones of the dies, the electrical pathways leading to the PHY circuitry are configured such that at least one of: an enable signal input to the die is to travel through at least some of the electrical pathways to enable ½ of the RX circuits and ½ of the TX circuit; and a disable signal input to the die is to travel through at least some of the electrical pathways to disable a remaining ½ of the RX circuits and ½ of the TX circuit.

Example 31 includes the subject matter of Example 28, wherein, for individual ones of the dies, the electrical pathways leading to the PHY circuitry are configured such that at least one of: an enable signal input to the die is to travel through at least some of the electrical pathways to enable ¼ of the RX circuits and ¼ of the TX circuit; and a disable signal input to the die is to travel through at least some of the electrical pathways to disable a remaining ¾ of the RX circuits and ¾ of the TX circuit.

Example 32 includes the subject matter of Example 28, wherein, for individual ones of the dies, some of the signal routing paths extend between corresponding ones of the electrical contact structures and all of the RX circuits, and some of the signal routing paths extend between corresponding ones of the electrical contact structures and all of the TX circuits.

Example 33 includes the subject matter of Example 28, wherein, for individual ones of the dies, some of the signal routing paths extend between corresponding ones of the electrical contact structures and a portion of the RX circuits, and some of the signal routing paths extend between corresponding ones of the electrical contact structures and a portion of the TX circuits.

Example 34 includes the subject matter of Example 33, wherein, for individual ones of the dies: the portion of the RX circuits includes ½ of the RX circuits and the portion of the TX circuits includes ½ of the TX circuits; or the portion of the RX circuits includes ¼ of the RX circuits and the portion of the TX circuits includes or ¼ of the TX circuits.

Example 35 includes the subject matter of Example 28, wherein, for individual ones of the dies, the RX circuits are at a first region of the die, and the TX circuits are at a second region of the die different from the first region.

Example 36 includes the subject matter of Example 28, wherein, for individual ones of the dies, the signal routing paths include electrically conductive traces and vias of the die.

Example 37 includes the subject matter of Example 28, wherein, for individual ones of the dies, the electrical contact structures include bumps.

Example 38 includes the subject matter of Example 37, wherein, for individual ones of the dies, the electrical contact structures include controlled collapse chip collection bumps.

Example 39 includes the subject matter of Example 28, wherein, for individual ones of the dies, a pitch between the electrical contact structures is between about 110 microns and about 130 microns.

Example 40 includes the subject matter of Example 28, wherein, for individual ones of the dies, a pitch between the electrical contact structures is between about 36 microns and about 55 microns.

Example 41 includes the subject matter of Example 28, wherein the package signal routing paths extend through and are in contact with material layers of the package substrate.

Example 42 includes the subject matter of Example 41, wherein the material layers including an organic material.

Example 43 includes the subject matter of Example 28, wherein the package substrate defines a cavity therein, the package further including an interconnect bridge within the cavity, the package signal routing paths extending within the interconnect bridge.

Example 44 includes the subject matter of Example 28, wherein the first die and the second die are identical to one another.

Example 45 includes the subject matter of Example 28, wherein; the package signal routing paths are first package signal routing paths; the plurality of dies further includes a third die and a fourth die disposed on the package substrate; the package substrate further includes second package signal routing paths extending between the third die and the second die to provide a device-to-device (D2D) signal interconnection therebetween; for individual ones of the first die and the second die: a first set of the signal routing paths extends between corresponding ones of the electrical contact structures and all of the RX circuits; and a second set of the signal routing paths different from the first set extends between corresponding ones of the electrical contact structures and all of the TX circuits; and for individual ones of the third die and the fourth die: a first set of the signal routing paths extends between corresponding ones of the electrical contact structures and a portion of the RX circuits; and a second set of the signal routing paths different from the first set extends between corresponding ones of the electrical contact structures and a portion of the TX circuits.

Example 46 method to fabricate a microelectronic device including: providing a substrate; providing a physical layer (PHY) circuitry on the substrate including a plurality of receive (RX) circuits and a plurality of transmit (TX) circuits; providing electrical contact structures at a bottom surface of the device; providing signal routing paths extending between the electrical contact structures on one hand, and, on another hand, at least some of the RX circuits or at least some of the TX circuits; and providing electrical pathways leading to the PHY circuitry; at least one of: providing an enable signal into the device through at least some of the electrical pathways to enable a portion of the PHY circuitry; and providing a disable signal into the device through at least some of the electrical pathways to disable a corresponding portion of the PHY circuitry.

Example 47 includes the subject matter of Example 46, wherein the electrical pathways include at least one of a fuse or a register to at least one of enable or disable said corresponding portion of the PHY circuitry.

Example 48 includes the subject matter of Example 46, wherein the electrical pathways leading to the PHY circuitry are configured such that at least one of: an enable signal input to the device is to travel through at least some of the electrical pathways to enable ½ of the RX circuits and ½ of the TX circuit; and a disable signal input to the device is to travel through at least some of the electrical pathways to disable a remaining ½ of the RX circuits and ½ of the TX circuit.

Example 49 includes the subject matter of Example 46, wherein the electrical pathways leading to the PHY circuitry are configured such that at least one of: an enable signal input to the device is to travel through at least some of the electrical pathways to enable ¼ of the RX circuits and ¼ of the TX circuit; and a disable signal input to the device is to travel through at least some of the electrical pathways to disable a remaining ¾ of the RX circuits and ¾ of the TX circuit.

Example 50 includes the subject matter of Example 46, wherein some of the signal routing paths extend between corresponding ones of the electrical contact structures and all of the RX circuits, and some of the signal routing paths extend between corresponding ones of the electrical contact structures and all of the TX circuits.

Example 51 includes the subject matter of Example 46, wherein some of the signal routing paths extend between corresponding ones of the electrical contact structures and a portion of the RX circuits, and some of the signal routing paths extend between corresponding ones of the electrical contact structures and a portion of the TX circuits.

Example 52 includes the subject matter of Example 51, wherein: the portion of the RX circuits includes ½ of the RX circuits and the portion of the TX circuits includes ½ of the TX circuits; or the portion of the RX circuits includes ¼ of the RX circuits and the portion of the TX circuits includes or ¼ of the TX circuits.

Example 53 includes the subject matter of Example 46, wherein the RX circuits are at a first region of the device, and the TX circuits are at a second region of the device different from the first region.

Example 54 includes the subject matter of Example 46, wherein the signal routing paths include electrically conductive traces and vias of the device.

Example 55 includes the subject matter of Example 46, wherein the electrical contact structures include bumps.

Example 56 includes the subject matter of Example 55, wherein the electrical contact structures include controlled collapse chip collection bumps.

Example 57 includes the subject matter of Example 46, wherein a pitch between the electrical contact structures is between about 110 microns and about 130 microns.

Example 58 includes the subject matter of Example 46, wherein a pitch between the electrical contact structures is between about 36 microns and about 55 microns.

What is claimed is:

1. A microelectronic device including:
a substrate;
physical layer (PHY) circuitry on the substrate including a plurality of receive (RX) circuits and a plurality of transmit (TX) circuits;
electrical contact structures at a bottom surface of the device;
signal routing paths extending between the electrical contact structures on one hand, and, on another hand, at least some of the RX circuits or at least some of the TX circuits; and
electrical pathways leading to the PHY circuitry and configured such that at least one of:
an enable signal input to the device is to travel through at least some of the electrical pathways to enable a portion of the PHY circuitry; or
a disable signal input to the device is to travel through at least some of the electrical pathways to disable a corresponding portion of the PHY circuitry.

2. The microelectronic device of claim 1, wherein the electrical pathways include at least one of a fuse or a register to at least one of enable or disable said corresponding portion of the PHY circuitry.

3. The microelectronic device of claim 1, wherein the electrical pathways leading to the PHY circuitry are configured such that at least one of:
an enable signal input to the device is to travel through at least some of the electrical pathways to enable ½ of the RX circuits and ½ of the TX circuit; or
a disable signal input to the device is to travel through at least some of the electrical pathways to disable a remaining ½ of the RX circuits and ½ of the TX circuit.

4. The microelectronic device of claim 1, wherein the electrical pathways leading to the PHY circuitry are configured such that at least one of:
an enable signal input to the device is to travel through at least some of the electrical pathways to enable ¼ of the RX circuits and ¼ of the TX circuit; or
a disable signal input to the device is to travel through at least some of the electrical pathways to disable a remaining ¾ of the RX circuits and ¾ of the TX circuit.

5. The microelectronic device of claim 1, wherein some of the signal routing paths extend between corresponding ones of the electrical contact structures and all of the RX circuits, and some of the signal routing paths extend between corresponding ones of the electrical contact structures and all of the TX circuits.

6. The microelectronic device of claim 1, wherein some of the signal routing paths extend between corresponding ones of the electrical contact structures and a portion of the RX circuits, and some of the signal routing paths extend between corresponding ones of the electrical contact structures and a portion of the TX circuits.

7. The microelectronic device of claim 6, wherein:
the portion of the RX circuits includes ½ of the RX circuits and the portion of the TX circuits includes or ½ of the TX circuits; or
the portion of the RX circuits includes ¼ of the RX circuits and the portion of the TX circuits includes or ¼ of the TX circuits.

8. The microelectronic device of claim 1, wherein the electrical contact structures include bumps.

9. The microelectronic device of claim 1, wherein a pitch between the electrical contact structures is between about 110 microns and about 130 microns.

10. The microelectronic device of claim 1, wherein a pitch between the electrical contact structures is between about 36 microns and about 55 microns.

11. A semiconductor package, comprising:
a package substrate;
two pairs of dies on the package substrate including a first pair of dies including a first die and a second die, and a second pair of dies including a third die and a fourth die, wherein:
individual ones of the dies include:
a die substrate;
physical layer (PHY) circuitry on the die substrate including a plurality of receive (RX) circuits and a plurality of transmit (TX) circuits;
electrical contact structures at a bottom surface of the die;
individual ones of the first die and the second die include signal routing paths extending between the electrical contact structures thereof on one hand, and, on another hand, all of the RX circuits and all the TX circuits thereof;
individual ones of the third die and the fourth die include signal routing paths extending between the electrical contact structures thereof on one hand, and, on another hand, a portion of the RX circuits and a portion of the TX circuits thereof,
wherein the package substrate includes first package signal routing paths extending between the first die and the second die to provide a device-to-device (D2D) signal interconnection therebetween, and second package signal routing paths extending between the first die and the second die to provide a device-to-device (D2D) signal interconnection therebetween.

12. The semiconductor package of claim 11, wherein the portion of the RX circuits includes ½ of the RX circuits, and the portion of the TX circuits includes ½ of the TX circuits.

13. The semiconductor package of claim 11, wherein the portion of the RX circuits includes ¼ of the RX circuits, and the portion of the TX circuits includes ¼ of the TX circuits.

14. The semiconductor package of claim 11, wherein, for individual ones of the dies, the RX circuits are at a first region of the die, and the TX circuits are at a second region of the die different from the first region.

15. The semiconductor package of claim 11, wherein, for individual ones of the dies, the signal routing paths include electrically conductive traces and vias of the die.

16. The semiconductor package of claim 11, wherein, for individual ones of the dies, the electrical contact structures include bumps.

17. The semiconductor package of claim 16, wherein, for individual ones of the dies, the electrical contact structures include controlled collapse chip collection bumps.

18. The semiconductor package of claim 11, wherein, for the first die and the second die, a pitch between the electrical contact structures is between about 110 microns and about 130 microns, and for individual ones of the third die and the fourth die, a pitch between the electrical contact structures is between about 36 microns and about 55 microns.

19. The semiconductor package of claim 11, wherein at least one of the first package signal routing paths and the second package signal routing paths extend through and are in contact with material layers of the package substrate.

20. An integrated circuit (IC) device assembly including:
a printed circuit board; and
a plurality of integrated circuit components coupled to the printed circuit board, individual ones of the integrated circuit components including one or more semiconductor packages, individual ones of the semiconductor packages including:
a package substrate;
a plurality of dies on the package substrate, individual ones of the dies including:
a die substrate;
physical layer (PHY) circuitry on the die substrate including a plurality of receive (RX) circuits and a plurality of transmit (TX) circuits;
electrical contact structures at a bottom surface of the die;
signal routing paths extending between the electrical contact structures on one hand, and, on another hand, at least some of the RX circuits or at least some of the TX circuits;
electrical pathways leading to the PHY circuitry and configured such that at least one of:
an enable signal input to the die is to travel through at least some of the electrical pathways to enable a portion of the PHY circuitry; or
a disable signal input to the die is to travel through at least some of the electrical pathways to disable a corresponding portion of the PHY circuitry; and
wherein the package substrate includes package signal routing paths extending between a first die of the plurality of dies and a second die of the plurality of dies to provide a device-to-device (D2D) signal interconnection therebetween.

21. The IC device assembly of claim 20, wherein, for individual ones of the dies, the electrical pathways include at least one of a fuse or a register to at least one of enable or disable said corresponding portion of the PHY circuitry.

22. The IC device assembly of claim 20, wherein, for individual ones of the dies, the electrical pathways leading to the PHY circuitry are configured such that at least one of:
an enable signal input to the die is to travel through at least some of the electrical pathways to enable ½ of the RX circuits and ½ of the TX circuit; or
a disable signal input to the die is to travel through at least some of the electrical pathways to disable a remaining ½ of the RX circuits and ½ of the TX circuit.

23. The IC device assembly of claim 20, wherein, for individual ones of the dies, the electrical pathways leading to the PHY circuitry are configured such that at least one of:
an enable signal input to the die is to travel through at least some of the electrical pathways to enable ¼ of the RX circuits and ¼ of the TX circuit; or
a disable signal input to the die is to travel through at least some of the electrical pathways to disable a remaining ¾ of the RX circuits and ¾ of the TX circuit.

24. A method to fabricate a microelectronic device including:
providing a substrate;
providing a physical layer (PHY) circuitry on the substrate including a plurality of receive (RX) circuits and a plurality of transmit (TX) circuits;
providing electrical contact structures at a bottom surface of the device;
providing signal routing paths extending between the electrical contact structures on one hand, and, on another hand, at least some of the RX circuits or at least some of the TX circuits; and
providing electrical pathways leading to the PHY circuitry;
at least one of:
providing an enable signal into the device through at least some of the electrical pathways to enable a portion of the PHY circuitry; or
providing a disable signal into the device through at least some of the electrical pathways to disable a corresponding portion of the PHY circuitry.

25. The method of claim 24, wherein the electrical pathways leading to the PHY circuitry are configured such that at least one of:
an enable signal input to the device is to travel through at least some of the electrical pathways to enable ½ of the RX circuits and ½ of the TX circuit; or
a disable signal input to the device is to travel through at least some of the electrical pathways to disable a remaining ½ of the RX circuits and ½ of the TX circuit.
